(19) United States
(12) Patent Application Publication
(10) Pub. No.: US 2023/0314740 A1
(43) Pub. Date: Oct. 5, 2023

(54) OPTICAL SEMICONDUCTOR MODULE AND MANUFACTURING METHOD OF THE SAME

(71) Applicant: Nippon Telegraph and Telephone Corporation, Tokyo (JP)

(72) Inventors: Hitoshi Wakita, Tokyo (JP); Kota Shikama, Tokyo (JP); Hiromasa Tanobe, Tokyo (JP); Yuzo Ishii, Tokyo (JP); Yoshiyuki Doi, Tokyo (JP); Satoshi Tsunashima, Tokyo (JP)

(21) Appl. No.: 18/005,883

(22) PCT Filed: Aug. 7, 2020
(86) PCT No.: PCT/JP2020/030394

§ 371 Date: Jan. 18, 2023

(51) Int. Cl. G02B 6/42; H01L 25/16; H01L 23/498; H01L 21/48; H01S 5/02251

(52) U.S. Cl. CPC G02B 6/4274; H01L 25/167; H01L 23/49822; H01L 21/4857; H01S 5/02251

(57) ABSTRACT

A module includes an electrical wiring layer, an optical wiring layer, an electrical element, and an optical element. The electrical wiring layer includes electrical wiring lines for propagating electrical signals. The optical wiring layer includes optical wiring lines that are formed over the electrical wiring layer and are designed for propagating optical signals. The electrical element is formed on the electrical wiring layer and is electrically connected to the electrical wiring lines. The optical element is formed on the optical wiring layer and is optically connected to the optical wiring lines.

### CROSS-REFERENCE TO RELATED APPLICATIONS

This patent application is a national phase filing under section 371 of PCT application no. PCT/JP2020/030394, filed on Aug. 7, 2020, which application is incorporated herein by reference in its entirety.

### TECHNICAL FIELD

The present invention relates to an optical semiconductor module and a method for manufacturing the optical semiconductor module.

### BACKGROUND

As a module that is smaller than a transceiver, a form enclosed in a metal housing called a gold box is known. For example, Non Patent Literature 1 discloses a receiver having a total bit rate of 100 Gb/s, which operates to multiplex four wavelengths (4λ×25 Gb/s). A module of this kind includes a wavelength separation element, an optical element such as a photodiode, an optical coupling portion (a lens), a light input/output unit (a receptacle), an electrical element (a transimpedance amplifier (TIA)), electrical wiring lines (a flexible printed circuit (FPC), or an expansion board), and a housing (a gold box for airtight sealing). For example, light that is input from the light input/output unit is input to the wavelength separation element via the optical coupling portion, is demultiplexed into four wavelengths, and is then further input to the optical element via the optical coupling portion. Each signal of the plurality of signals photoelectrically converted by the optical element is input to the electrical element (a TIA), and is output via the electrical wiring lines (a FPC, or an expansion board).

### CITATION LIST

### Non Patent Literature

Non Patent Literature 1: Y. Doi et al., “Compact ROSA for 100-Gb/s (4×25 Gb/s) Ethernet with a PLC-based AWG demultiplexer”, Optical Fiber Communication Conference and Exposition and the National Fiber Optic Engineers Conference, 13582006, 2013.

### SUMMARY

### Technical Problem

However, the conventional module described above has the following problem. In the module described above, an optical device is normally mounted in the housing formed with ceramics or a metal (Non Patent Literature 1). While ceramics or metal housings are highly reliable because of their rigidity, such housings are large in size, and are not easily mounted on a board with high density.

Embodiments of the present invention can solve the above problem, and aim to reduce the size of a module, and enable mounting with higher density.

### Solution to Problem

An optical semiconductor module according to embodiments of the present invention includes: an electrical wiring layer that includes an electrical wiring line for propagating an electrical signal and supplying electrical power; an optical wiring layer that is formed over or under the electrical wiring layer, and includes an optical wiring line for propagating an optical signal; and an optical element that is formed on the optical wiring layer, is electrically connected to the electrical wiring layer, and is optically connected to the optical wiring line.

An optical semiconductor module according to embodiments of the present invention includes: an electrical wiring layer that includes an electrical wiring line for propagating an electrical signal; and an optical element that is formed on the electrical wiring layer.

Further, an optical semiconductor module manufacturing method according to embodiments of the present invention includes: a first step of forming an electrical wiring layer over a support substrate, the electrical wiring layer including an electrical wiring line for propagating an electrical signal and supplying electrical power; a second step of forming an optical wiring layer over the support substrate, the optical wiring layer including an optical wiring line for propagating an optical signal; a third step of mounting an electrical element on the electrical wiring layer, and electrically connecting the electrical element to the electrical wiring line; a fourth step of mounting an optical element on the optical wiring layer, and optically connecting the optical element to the optical wiring line; a fifth step of performing resin sealing, using one or more kinds of resins; and a sixth step of removing the support substrate. The first step, the second step, and the third step are carried out at a wafer level or a panel level, and the optical semiconductor module manufacturing method further includes a seventh step of dividing the resultant module into individual modules.

### Advantageous Effects of Embodiments of the Invention

As described above, according to embodiments of the present invention, the module size can be made smaller, and mounting can be performed at a higher density.

### BRIEF DESCRIPTION OF THE DRAWINGS

FIG. 1A is a cross-sectional diagram illustrating a configuration of an optical semiconductor module according to a first embodiment of the present invention.

FIG. 1B is a cross-sectional diagram illustrating another configuration of an optical semiconductor module according to the first embodiment of the present invention.

FIG. 1C is a cross-sectional diagram illustrating another configuration of an optical semiconductor module according to the first embodiment of the present invention.

FIG. 2A is a configuration diagram illustrating a state of an optical semiconductor module in an intermediate step for explaining a method for manufacturing the optical semiconductor module according to the first embodiment of the present invention.

FIG. 2B is a configuration diagram illustrating a state of the optical semiconductor module in an intermediate step for explaining the method for manufacturing the optical semiconductor module according to the first embodiment of the present invention.

FIG. 2C is a configuration diagram illustrating a state of the optical semiconductor module in an intermediate step for explaining the method for manufacturing the optical semiconductor module according to the first embodiment of the present invention.

FIG. 2D is a configuration diagram illustrating a state of the optical semiconductor module in an intermediate step for explaining the method for manufacturing the optical semiconductor module according to the first embodiment of the present invention.

FIG. 2E is a configuration diagram illustrating a state of the optical semiconductor module in an intermediate step for explaining the method for manufacturing the optical semiconductor module according to the first embodiment of the present invention.

FIG. 2F is a configuration diagram illustrating a state of the optical semiconductor module in an intermediate step for explaining the method for manufacturing the optical semiconductor module according to the first embodiment of the present invention.

FIG. 3A is a configuration diagram illustrating a configuration of an optical semiconductor module of Example 1.

FIG. 3B is a configuration diagram illustrating a configuration of an optical semiconductor module of Example 1.

FIG. 3C is a configuration diagram illustrating a configuration of an optical semiconductor module of Example 1.

FIG. 3D is a configuration diagram illustrating a configuration of an optical semiconductor module of Example 1.

FIG. 3E is a configuration diagram illustrating a configuration of an optical semiconductor module of Example 1.

FIG. 4 is a configuration diagram illustrating a configuration of an optical semiconductor module of Example 2.

FIG. 5 is a configuration diagram illustrating a configuration of an optical semiconductor module of Example 3.

FIG. 6 is a configuration diagram illustrating a configuration of an optical semiconductor module of Example 4.

FIG. 7A is a configuration diagram illustrating a configuration of an optical semiconductor module of Example 5.

FIG. 7B is a configuration diagram illustrating a configuration of an optical semiconductor module of Example 5.

FIG. 8A is a configuration diagram illustrating a configuration of an optical semiconductor module of Example 6.

FIG. 8B is a configuration diagram illustrating a configuration of an optical semiconductor module of Example 6.

FIG. 9 is a configuration diagram illustrating a configuration of an optical semiconductor module of Example 7.

FIG. 10 is a configuration diagram illustrating a configuration of an optical semiconductor module of Example 8.

FIG. 11A is a configuration diagram illustrating a configuration of an optical semiconductor module of Example 9.

FIG. 11B is a configuration diagram illustrating a configuration of an optical semiconductor module of Example 9.

FIG. 12A is a cross-sectional diagram illustrating a configuration of an optical semiconductor module according to a second embodiment of the present invention.

FIG. 12B is a cross-sectional diagram illustrating a configuration of an optical semiconductor module according to the second embodiment of the present invention.

FIG. 12C is a cross-sectional diagram illustrating another configuration of an optical semiconductor module according to the second embodiment of the present invention.

FIG. 12D is a cross-sectional diagram illustrating another configuration of an optical semiconductor module according to the second embodiment of the present invention.

FIG. 12E is a cross-sectional diagram illustrating another configuration of an optical semiconductor module according to the second embodiment of the present invention.

### DETAILED DESCRIPTION OF ILLUSTRATIVE EMBODIMENTS

The following is a description of optical semiconductor modules according to embodiments of the present invention.

### First Embodiment

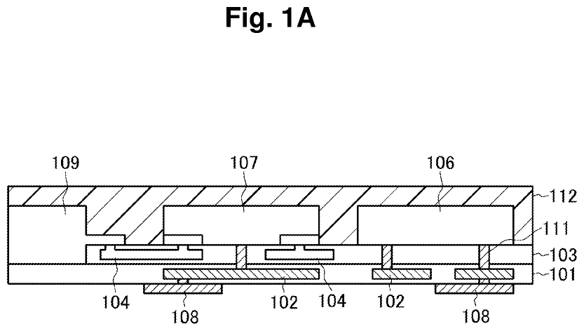

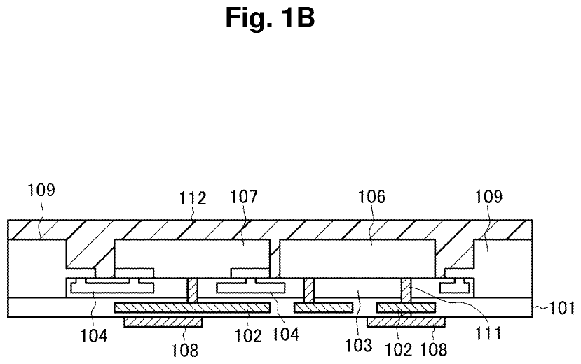

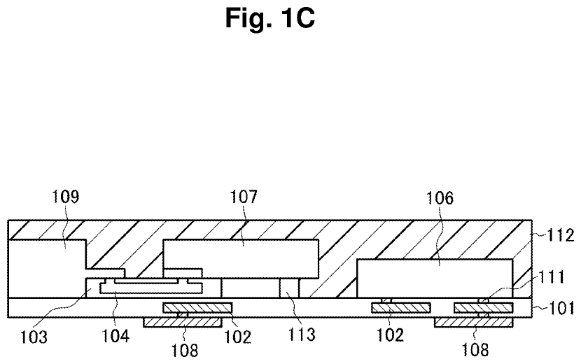

First, an optical semiconductor module according to a first embodiment of the present invention is described with reference to FIGS. 1A, 1B, and 1C. This optical semiconductor module includes an electrical wiring layer 101, an optical wiring layer 103, and an optical element 107. In this example, the optical wiring layer 103 is formed on the electrical wiring layer 101. The optical wiring layer 103 can also be disposed under the electrical wiring layer 101.

The electrical wiring layer 101 includes electrical wiring lines 102 for propagating electrical signals. In this example, an electrical element 106 is further included. The electrical element 106 is formed on the electrical wiring layer 101, and is electrically connected to the electrical wiring lines 102. The optical wiring layer 103 includes optical wiring lines 104 that are formed over the electrical wiring layer 101 and are designed for propagating optical signals. Note that the electrical wiring lines 102 and the optical wiring lines 104 extend in a plane direction of the electrical wiring layer 101.

Further, the electrical element 106 is formed over the electrical wiring layer 101 and is electrically connected to the electrical wiring lines 102. The electrical element 106 is electrically connected to the electrical wiring lines 102 via contact wiring lines iii, for example. The optical element 107 is formed on the optical wiring layer 103, and is optically connected to the optical wiring lines 104. Further, terminals 108 are formed on the back surface of the electrical wiring layer 101, and are electrically connected to the electrical wiring lines 102.

The optical element 107 can be a light emitting element such as a semiconductor laser or a light emitting diode, a photoelectric conversion element such as a photodiode, or an optical modulation element, for example. Alternatively, the optical element 107 can be an element that includes a light receiving unit designed by a well-known silicon photonics technology, and a multiplexer/demultiplexer formed with an optical waveguide. Note that the optical element 107 is not necessarily in physical contact with the optical wiring layer 103. Also, the optical element 107 or part of the optical element 107 may be inserted into the optical wiring layer 103 in a thickness direction. In this case, the optical element 107 and the optical wiring lines 104 are optically connected inside the optical wiring layer 103.

The electrical element 106 can be a driver element for driving the optical element 107 formed with an element described above, a transimpedance amplifier (TIA) for amplifying photoelectrically converted signals, or a PHY device, for example. Alternatively, the electrical element 106 can be a programmable logic device (PLD) such as a field-programmable gate array (FPGA), a microcomputer chip, a memory, a control IC, or a power supply IC.

Also, the electrical element 106 can be in the form of a bare chip, a subcarrier-mounted form, the form of a chip size package (CSP), or the like. Alternatively, the electrical element 106 can have a structure in which chips are stacked in multiple stages. Meanwhile, the terminals 108 can be solder bumps, solder balls, or flat electrode pads, for example.

Also, a light input/output unit 109 that is optically connected to the optical element 107 is provided. In this example, the light input/output unit 109 is formed on the optical wiring layer 103, and is optically connected to the optical element 107 via an optical wiring line 104. The light input/output unit 109 may be disposed at one end as illustrated in FIG. 1A, or may be disposed at both ends as illustrated in FIG. 1B. The light input/output unit 109 achieves optical connection between this module and the outside of the module at high efficiency, and can be an MT ferrule having a structure similar to a well-known mechanical transfer (MT) connector, for example. Alternatively, a fitting structure compatible with an MT ferrule can be used. Further, the light input/output unit contains a plurality of short fibers, for example.

Also, the optical wiring layer 103 may be formed over the region in which the electrical element 106 is disposed as illustrated in FIGS. 1A and 1B, or may be partially formed in the region in which the optical element 107 is disposed as illustrated in FIG. 1C, instead of in the region in which the electrical element 106 is disposed. In a case where the optical wiring layer 103 is also provided in the region in which the electrical element 106 is disposed, the contact wiring lines 111 are formed to penetrate the optical wiring layer 103. Further, in a case where the optical wiring layer 103 is partially provided in the region in which the optical element 107 is disposed as illustrated in FIG. 1C, a step might be formed between the region in which the optical wiring layer 103 exists and the region in which the optical wiring layer 103 does not exist in the region in which the optical element 107 is disposed. In such a case, a spacer 113 is disposed between the lower surface of the optical element 107 and the electrical wiring layer 101. The spacer 113 can be formed with a solder bump or the like, for example.

Also, a protective layer 112 is formed over the electrical wiring layer 101 so as to cover the optical element 107. In this example, the protective layer 112 also covers the electrical element 106. The protective layer 112 is a component for sealing each element, and can be formed with a cured resin such as epoxy, for example. Although not illustrated, the optical element 107 may include an optical connector that is optically connected to the optical element 107. Although not illustrated either, a heat dissipation member such as a heat sink can be provided on and in contact with the electrical element 106 and the optical element 107.

Both the electrical wiring layer 101 and the optical wiring layer 103 have a thickness of about several microns to several tens of microns. In other words, by a well-known semiconductor device technology or a well-known silicon photonics technology, both the electrical wiring layer 101 and the optical wiring layer 103 can be easily designed to have a thickness of about several microns to several tens of microns. With such a configuration, the module size can be made smaller, and higher-density mounting can be easily realized. Further, at least either the electrical wiring layer 101 or the optical wiring layer 103 can have a so-called multi-layer wiring structure.

Even with a multi-layer structure, the form of a film is maintained. The electrical wiring layer 101 and the optical wiring layer 103 that are in the form of a thin film serve as the base surfaces on which the electrical element 106 and the optical element 107 are mounted, but are clearly different from a rigid and thick substrate that is used in a conventional module. Therefore, to provide the module with strength, the electrical element 106, the optical element 107, and the light input/output unit 109 are sealed with the protective layer 112 so that the mechanical strength is enhanced. Having the protective layer 112 formed with cured resin (plastic), the module having the protective layer 112 formed thereon can obtain a mechanical strength comparable to that of a module formed on a conventional rigid and thick substrate.

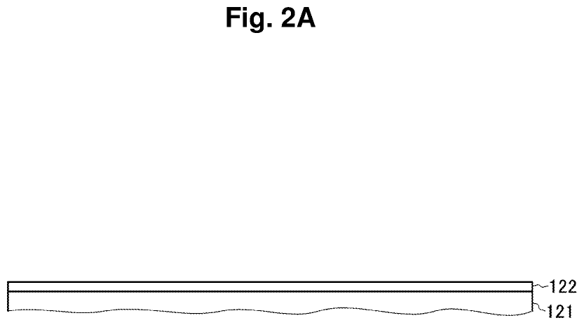

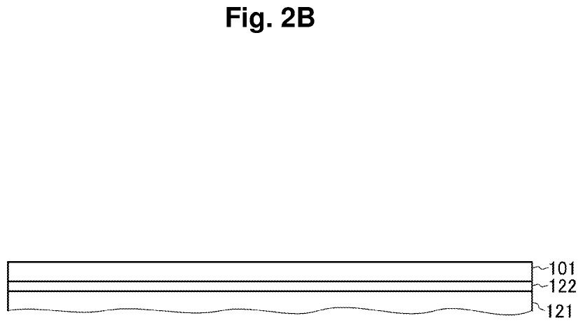

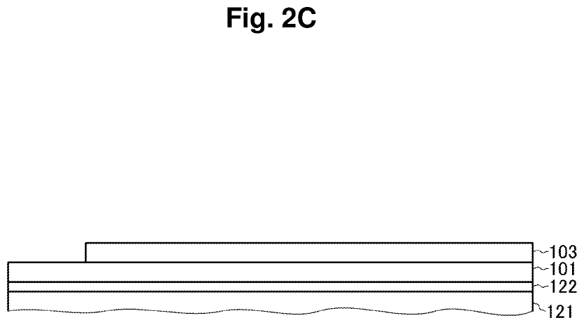

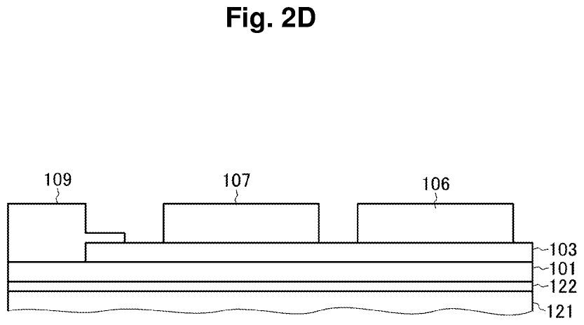

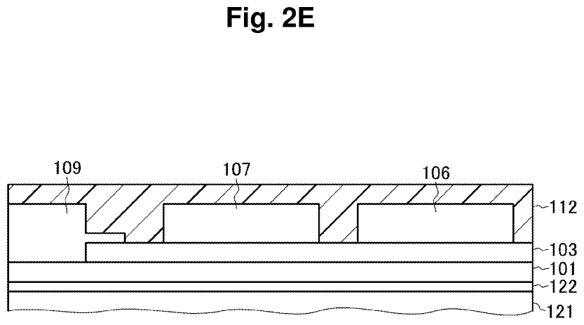

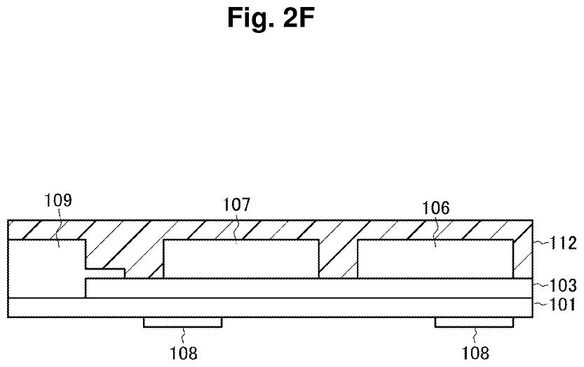

Next, a method for manufacturing the optical semiconductor module according to the first embodiment of the present invention is described with reference to FIGS. 2A to 2F.

First, as illustrated in FIG. 2A, a support substrate 121 that is formed with glass, metal, semiconductor, or the like and has a smooth surface is prepared, and a release layer 122 is formed on the support substrate 121. Next, as illustrated in FIG. 2B, the electrical wiring layer 101 including the electrical wiring lines 102 for propagating electrical signals is formed over the support substrate 121 (a first step). In this example, the electrical wiring layer 101 is formed on the release layer 122.

The electrical wiring layer 101 has a configuration in which layers in which wiring lines formed with a metal such as Cu or Al are formed, and insulating layers formed with an insulating material such as polyimide are alternately stacked. The wiring lines arranged with the insulating layers interposed in between are connected by through wiring lines penetrating the insulating layers. The wiring lines and the through wiring lines can be formed by a photoprocess such as a known photolithography technique and etching technique, or a laser machining process, for example.

Next, as illustrated in FIG. 2C, the optical wiring layer 103 including the optical wiring lines 104 for propagating optical signals is formed over the support substrate 121 (a second step). In this example, the optical wiring layer 103 is formed on the electrical wiring layer 101. The optical wiring layer 103 can be a well-known optical waveguide structure. For example, a lower cladding layer is formed, and a core layer is formed on the lower cladding layer. The core layer is formed with a transparent resin through which light having a target wavelength is transmitted, for example. For example, the core layer can be formed with a resin such as polyimide, fluorinated polyimide, epoxy, acrylic, or siloxane. Also, the core layer can be formed with an organic-inorganic hybrid material, a resin formed by substituting deuterium, fluorine, or the like with halogen, or the like. Note that there may be a configuration in which the optical wiring layer 103 is not formed. In this case, this step is not to be carried out.

Next, patterning is performed on the core layer, to form a core wiring structure for confining optical signals. The patterning can be performed by a known photoprocess or a well-known nanoimprint technique, for example. Next, an upper cladding layer is formed on the formed core wiring structure. The upper cladding layer may be formed to cover the entire region of the core wiring structure, or may be formed so that part of the core wiring structure is exposed. Note that a pattern that exposes not only the optical wiring layer 103 but also the electrical wiring layer 101 can be provided to mount the light input/output unit 109 after one of the steps illustrated in FIGS. 2C and 2D.

Next, as illustrated in FIG. 2D, the electrical element 106 is mounted over the electrical wiring layer 101, to electrically connect the electrical element 106 to the electrical wiring lines 102 (a third step), and the optical element 107 is mounted on the optical wiring layer 103, to optically connect the optical element 107 to the optical wiring lines 104 (a fourth step). For example, the electrical terminal of the electrical element 106 and the optical coupling portion of the optical element 107 are located on the lower surfaces or at lower portions of side surfaces of the respective elements. At this point of time, the light input/output unit 109 for inputting from and outputting to the outside is also formed or mounted. The light input/output unit 109 can be formed with a well-known optical receptacle member. Note that there may be a configuration in which the electrical element 106 is not mounted. Also, there may be a manufacturing method by which the electrical element is mounted after the next step (FIG. 2E).

Next, as illustrated in FIG. 2E, the protective layer 112 that covers the electrical element 106 and the optical element 107 is formed (a fifth step). For example, the protective layer 112 can be formed by molding a resin by transfer molding, compression molding, or the like, and then sealing the resin. Next, the release layer 122 is removed, for example, so that the support substrate 121 is removed (a sixth step). Next, as illustrated in FIG. 2F, the terminals 108 are formed on the back surface of the electrical wiring layer 101. Lastly, the module is divided into individual modules by cutting with a dicing saw or a laser dicer (a seventh step).

For example, the support substrate 121 having a large area is used, and the first step, the second step, the third step, and the like, such as manufacturing of a plurality of modules on the support substrate 121 at once, are carried out at a wafer level or a panel level. Thus, excellent mass productivity can be achieved, and the manufacturing costs can be lowered. Also, this module does not require an interposer or the like, and accordingly, the parts cost can be lowered. Note that, in the above description, the step of forming the optical wiring layer 103 is carried out after the step of forming the electrical wiring layer 101. However, the electrical wiring layer 101 can be formed after the optical wiring layer 103 is formed first.

In the description below, the embodiment will be explained in greater detail through Examples.

### EXAMPLE 1

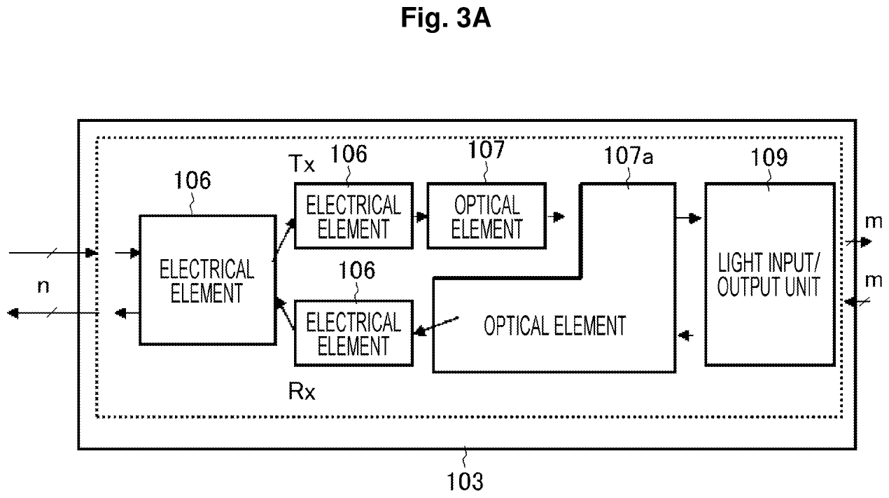

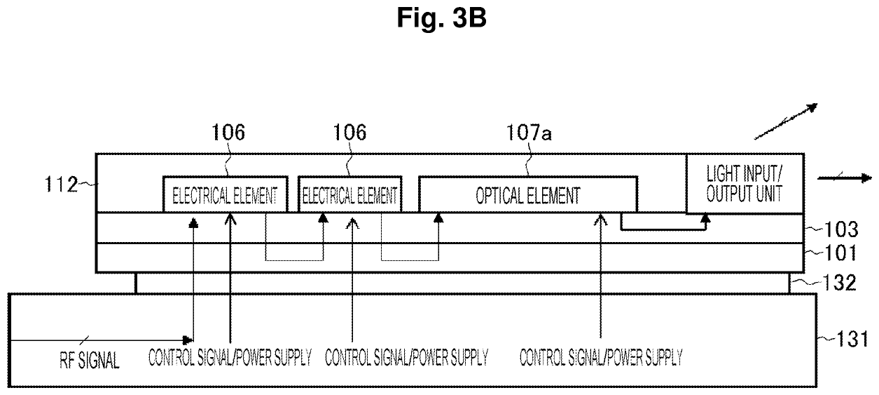

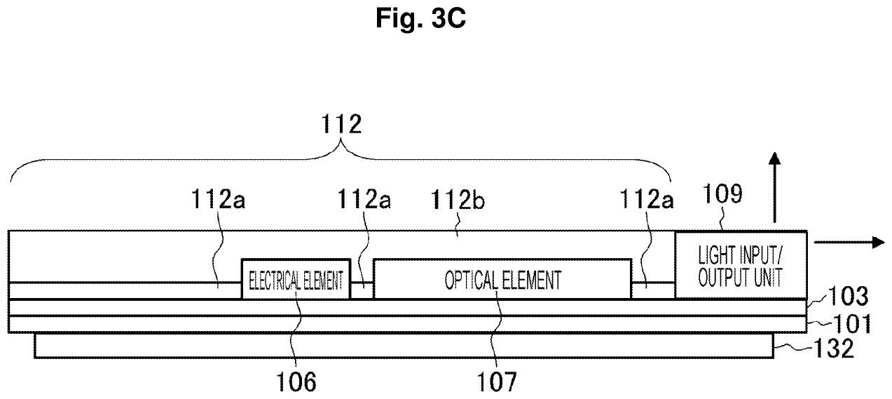

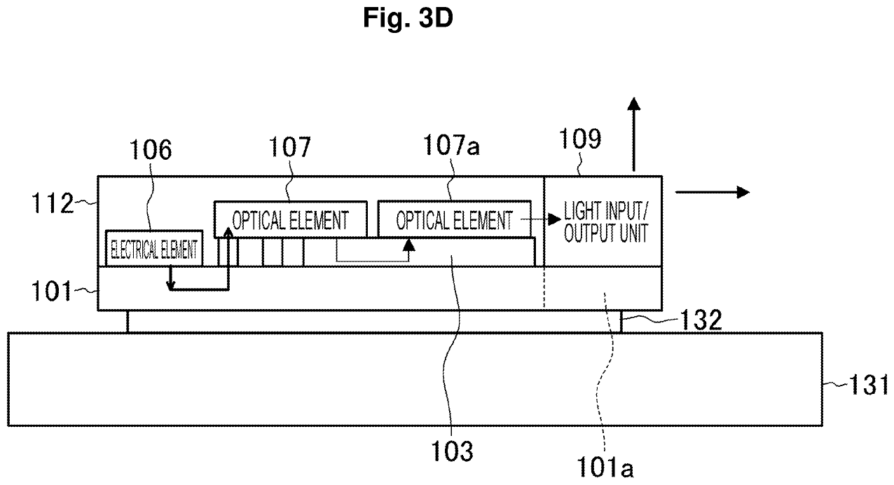

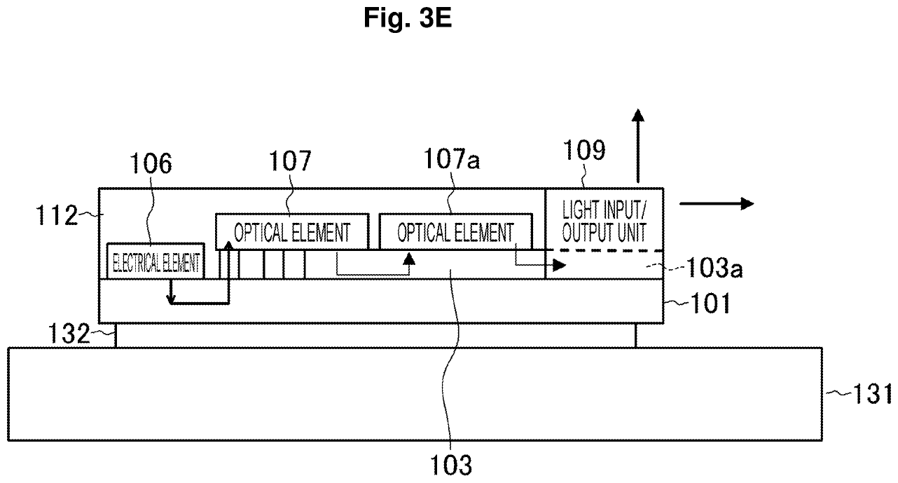

First, Example 1 is described with reference to FIGS. 3A to 3D. The optical element 107 is a semiconductor laser chip, for example, and can be formed with a compound semiconductor such as indium phosphide. The optical element 107 that is a semiconductor laser is an electrical-optical conversion element, and emits light having a desired wavelength to the right in the drawing in accordance with a supplied electrical signal, so that the light propagates to the optical waveguide of the optical wiring layer 103 via the optical coupling portion. The optical signal having propagated in the optical waveguide is taken out from the light input/output unit 109 to the outside.

The light input/output unit 109 has an optical connector structure that is a so-called optical receptacle structure in which a plug-type optical fiber can be fitted, for example. An electrical signal for causing the optical element 107 to operate is connected to an electrical wiring line of the electrical wiring layer 101 via an electrical terminal (not illustrated) formed on the optical element 107 on the side of the electrical wiring layer 101. The electrical terminal of the optical element 107 is connected to any one of the electrical elements 106 via an electrical wiring line of the electrical wiring layer 101.

The electrical elements 106 are laser driver chips, for example. Another electrical terminal of the electrical element 106 is also connected to an electrical wiring line of the electrical wiring layer 101, and can be connected to the outside via an electrical input/output unit 132 formed on the lower side of the electrical wiring layer 101. The electrical input/output unit 132 includes a plurality of terminals 108 formed with solder bumps, solder balls, or flat electrode pads, and is a ball grid array or a land grid array, for example. Note that the electrical input/output unit 132 is disposed on a module substrate 131. The electrical input/output unit 132 can input and output not only electrical signals, but also signals including a power supply, a ground, a control signal, and the like.

Meanwhile, the optical element 107 can be an external modulation laser chip in which modulators are integrated in one chip, or a laser chip including a semiconductor amplifier (SOA). Also, a chip (a silicon photonics chip) formed by a so-called silicon photonics technology can be combined with these light emitting elements, to form an optical element 107a. The silicon photonics chip requires a light emitting element serving as a light source. In this example, the optical element 107a is an optical-electrical conversion element including a multiplexer circuit.

The light input/output unit 109 is an MT ferrule including a plurality of short fibers, for example. The short fibers are optically connected to the optical element 107 and the optical element 107a. Further, like a well-known pin-fitting MT connector structure, the MT ferrule has two guide holes into which guide pins can be inserted on both sides. Here, by fitting and inserting an MT connector having guide pins, it is possible to realize insertable and removable optical connection outside the module. The guide holes into which the guide pins are inserted are not filled with any molding material. A refractive index matching agent having the same refractive index as that of the core is applied to the end face of the connector, and the gap is filled with the refractive index matching agent, so that reflection can be prevented.

Note that a polymer waveguide can be used in place of the short fibers. Also, instead of the MT ferrule, a microhole component having a plurality of microholes into which bare fibers without coatings can be inserted is provided, and an aligned bare fiber array is inserted from the outside of the module, so that insertable and removable optical connection can be realized as above.

Also, an optical path conversion structure may be provided in the optical connecting portion or part of the optical wiring layer 103, so that optical connection can be realized from the upper surface of the module. As the optical path conversion structure, a mirror, a bent fiber, a bent waveguide, a grating coupler, or the like can be used, for example. Likewise, in a case where light is connected from the upper surface of the module, a guide structure in which an MT connector, a bare fiber array, or the like can be fitted or mounted is provided. For example, guide pin holes are provided, so that an MT ferrule can be inserted and removed as described above. Also, the guide pins may be designed to protrude. In a case where optical connection is established from the upper surface, connection can be conducted using a known prism mirror and an MT connector component that has an optical path conversion function and includes a microlens therein.

Further, the optical element 107 and the optical element 107a may be passive devices that do not require electrical signal inputs, such as couplers, splitters, and wavelength multiplexing/demultiplexing filters. In many cases, these passive devices are normally formed with a dielectric material such as quartz, or a polymer material.

Also, active devices to function as the optical element 107 and the optical element 107a are not limited to light sources and modulators, but can be light receiving elements, switches, or wavelength conversion elements. Further, chips in which these elements are integrated as an array, or chips in which a plurality of kinds of elements are integrated may be used. Also, a plurality of identical chips may be provided, and the identical chips may be arranged adjacent to each other, or may be stacked. Further, these chips are not limited to a form of being mounted as bare chips, but may be mounted on subcarriers.

Meanwhile, each electrical element 106 is not necessarily a laser driver chip, but may be a TIA, a PHY device, a control IC, or the like. For example, the electrical element 106 on the left side of FIGS. 3A and 3B can be a PHY device. Other than a bare chip, a form mounted on a subcarrier, or a form such as a chip size package (CSP) may be adopted. Further, it is also possible to adopt a structure in which chips are stacked in multiple stages.

The light input/output unit 109, such as an optical receptacle member, for example, is also mounted and introduced during the manufacturing process, and, after this module is mounted on a wiring substrate, such as a module substrate, for example, fiber connection can be performed. Thus, mounting properties can be enhanced. In this module, the optical fibers are not pigtails but connector interfaces. Accordingly, fiber breakage during handling is prevented, and the module is suitable for conveyance, assembling, and mounting by an automatic machine.

Also, the formation of the protective layer 112 leads to excellent dust-proofness (prevention of entrance of dust during and after the assembling) and improvement in resistance to environment (moisture resistance and the like). Further, if a black resin or the like is used as the mold resin forming the protective layer 112, the influence of stray light inside the module can be reduced.

As electrical and optical wiring lines are formed through the steps of forming the electrical wiring layer 101 and the optical wiring layer 103, and resin sealing for forming the protective layer 112 is performed after the element mounting, the height of the module structure can be reduced, and the heat dissipation properties thereof can also be enhanced. Further, as the protective layer 112 is formed with a resin obtained by dispersing and mixing a silica filler, a diamond filler, or the like as the aggregate, it is possible to enhance the thermal conductive properties, and further lower the linear expansion coefficient. This of course leads to further improvement of the heat dissipation properties and the thermal deformation characteristics of the module body. As the module size is made smaller, the amount of deformation due to thermal expansion can be reduced to a small amount, which is preferable in terms of reliability.

The material of the insulating layer (the interlayer insulating layer) of the electrical wiring layer 101 is normally polyimide or modified polyimide, but may be some other insulating material. The thickness of the insulating layer of the electrical wiring layer 101 is about several μm to several tens of μm. Also, since the layer of electrical wiring lines can be formed through a step similar to the postprocessing of the chip manufacturing process, the line width can be set to several μm, and the wiring pitch can be set to several μm in a planar view. Further, with the use of the state-of-the-art semiconductor device manufacturing technology, both the line width and the wiring pitch can be in the order of submicrons.

The thickness of the insulating layer of the electrical wiring layer 101 is on the order of several μm to several tens of μm as described above, and, by appropriately designing the wiring dimensions, it is possible to set the single-phase characteristic impedance to 50 Ω, or the differential characteristic impedance to 100 Ω, even for a radio-frequency signal. Also, as described above, since the wiring width and the wiring pitch are small (narrow), and wiring lines can be provided at high density, the wiring length between elements can be shortened, and it is possible to achieve lower power consumption, a higher speed, and a decrease in the number of components (elimination of electrical elements, or the like). Further, since any through hole vias (through silicon vias: TSVs) are not required, there are no stubs in the wiring lines, unnecessary reflection of signals is reduced, impedance matching is easy, and signal quality is higher. Also, a passive circuit such as an inductor, an antenna, a resistor, a balun, or a capacitor can be formed in the electrical wiring layer 101.

Examples of the core material forming the optical wiring layer 103 include acrylic, epoxy, polyimide, siloxane, and polynorbornene. Also, the optical wiring layer 103 may be either a single-mode waveguide or a multimode waveguide. Further, the core layer forming the optical wiring layer 103 is not necessarily a single layer, but may be a multi-layer. Also, the optical wiring lines in the optical wiring layer 103 may intersect in the same plane.

The optical wiring layer 103 can also be disposed over or under the electrical wiring layer 101, or between layers, and may be formed to continue to the electrical wiring layer 101 or be bonded to the electrical wiring layer 101. The optical coupling portion may be designed to have a structure that is optically coupled by a technique such as adiabatic or evanescent coupling, or optical coupling by resin spatial propagation, in addition to end face coupling (edge coupling).

Also, with the use of optical wiring lines, it is possible not only to input and output light to the outside, but also to optically connect the optical elements 107 in the module to each other with low loss. An optical confinement structure is appropriately designed, so that the optical wiring lines can be densely disposed in the optical wiring layer 103.

Further, as another additional effect, the optical wiring lines (the optical wiring layer) may be added later so that the optical coupling between the optical elements 107 can be finely adjusted. Also, as the optical wiring lines are formed in multiple layers, functions can be divided into a first layer and a second layer. For example, the first layer may be a complicated optical circuit, and the second layer may be used for optical coupling. The first layer may be used as the test/inspection wiring lines during the manufacturing process, and may be peeled off in the step of removing the support substrate.

By the manufacturing method described above, it is also possible to form the optical wiring lines as rewiring lines after the support substrate is removed, and, in the rewiring step, the core can be formed by electron beam drawing, 3D molding, or the like, after a resin that functions as the cladding of an optical waveguide is applied. As such a manufacturing method is adopted, pitch conversion becomes possible in an optical function element having channels at high density, and optical function elements (the optical elements 107) having high mounting tolerance can be turned into a module.

In a case where chips having optical multiplexing/demultiplexing functions are used as the optical elements 107 to be mounted, the optical coupling portions are disposed at a high density in accordance with the number of channels. However, the pitch can be expanded via the optical wiring lines 104 integrated in the optical wiring layer 103, and the mounting tolerance can also be increased in the optical elements 107 integrated at a high density. For example, as for narrow-pitch waveguide layers formed in the optical elements 107, the pitch between the waveguides in the optical wiring layer 103 can be increased to the pitch in the light input/output unit 109 connected in the subsequent stage, such as the pitch in a fiber array or the pitch of the connector receptacles, for example, and the mounting properties of the light input/output unit 109 can be enhanced with these components.

The protective layer 112 formed by resin molding enables collective production on a wafer or a panel, rigidly fixes the optical wiring lines and the optical elements 107 integrated on the optical wiring layer 103 to be mounted, enhances moisture resistance, and functions as a protector for generating impact resistance. Also, the handleability of the optical elements 107 in the mounting step is greatly increased.

Further, the protective layer 112 can be formed by overlapping and applying a plurality of molding materials. In other words, the protective layer 112 can have a multi-layer structure formed with different resins. For example, as illustrated in FIG. 3C, the protective layer 112 can include a first protective layer 112a and a second protective layer 112b. The first protective layer 112a can be used as an underfill material for the purpose of abbreviating the stress on the elements, for example. Also, a refractive index matching agent can be used to enhance the coupling rate between the optical element 107 and the optical wiring layer 103.

Further, in the case of a configuration in which the optical element 107 including an optical element or a planar lightwave circuit (PLC) according to the silicon photonics technology, and the light input/output unit 109 are mounted adjacent to each other, the optical connection between these components can be of a spatial optics type or an edge coupling type. Regarding such optical connection, if the first protective layer 112a formed in contact with the optical element 107 and the light input/output unit 109 is formed with a resin having optical transparency or a refractive index matching function, the above-described optical connection becomes possible. In this case, the first protective layer 112a functions as a light propagation portion that propagates the light for optical connection between the optical element 107 and the light input/output unit 109 (the other optical element) in the plane direction of the electrical wiring layer 101.

Furthermore, when the second protective layer 112b is formed to overlap the first protective layer 112a as the light propagation portion, sealing and strength can be enhanced. In this manner, the impact resistance and the moisture resistance of the module body can be increased, without degradation of the optical characteristics even in a spatial optical system and an edge coupling system.

In this modular structure, the electrical element 106 may include an electrical signal processing circuit such as a PHY device. In addition to the PHY device, a drive circuit that drives a semiconductor laser, an electro absorption modulator integrated laser diode (EML), or the like may be included as the electrical element 106 on the Tx side at a subsequent stage. An electrical signal may be converted into an optical signal by the EML, and the optical signal may be multiplexed by a multiplexer circuit formed in the optical element 107a at a subsequent stage by the silicon photonics technology. The multiplexed optical signal is output to the outside of the module structure via the light input/output unit 109.

On the Rx side, a circuit that demultiplexes the optical signal input from the light input/output unit 109 may be formed in the optical element 107a. The light input/output unit 109 and the optical element 107 (the optical element 107a) are connected via the optical wiring layer 103. The demultiplexed optical signal mentioned above is converted into an electrical signal via a light receiving element such as a Ge photodiode formed in the optical element 107 (the optical element 107a), for example. This converted electrical signal is input to the electrical element 106 that is a PHY device via the electrical element 106 such as a TIA, and is transmitted to the outside of the module via the electrical input/output unit 132.

Further, in the structure illustrated in FIG. 3D, the optical coupling portion of the optical element 107a and the light input/output unit 109 are optically connected via the protective layer 112 disposed in between. This optical connection can be of an edge coupling type or a coupling type, such as resin spatial propagation, for example. In this case, the resin material forming the protective layer 112 is preferably a material having high transparency, a matching refractive index, and small variation in the thermal expansion coefficient. For example, in a case where the wavelength of the target light is in the 1.55 μm band, the material to be used for the protective layer 112 is an acrylic resin having transparency and a refractive index of about 1.5, an epoxy resin, silicone (polysiloxane), a fluorinated polymer, a fluorinated polyimide, polynorbornene, oxetane, an organic-inorganic hybrid material, a substitution material of any of these materials, or the like.

Note that this package includes an overlap portion 101a in which part of the electrical wiring layer 101 and part of the light input/output unit 109 overlap each other. For example, in the overlap portion 101a, part of the light input/output unit 109 is incorporated into the electrical wiring layer 101. For example, the light input/output unit 109 penetrates from the surface of the electrical wiring layer 101 in the thickness direction on the bottom surface side of the light input/output unit 109, and forms the overlap portion Iola in which these components overlap each other.

Note that, in this package, the light input/output unit 109 may be disposed on the upper surface of the electrical wiring layer 101, or may include the overlap portion 101a in which part of the electrical wiring layer 101 and part of the light input/output unit 109 overlap each other. In the latter case, for example, part of the light input/output unit 109 is incorporated into the electrical wiring layer 101, to form the overlap portion 101a. For example, the light input/output unit 109 penetrates from the surface of the electrical wiring layer 101 in the thickness direction on the bottom surface side of the light input/output unit 109, and forms the overlap portion 101a in which these components overlap each other.

Although not illustrated in the drawings, the light input/output unit 109 may be incorporated not only into the electrical wiring layer 101 but also into the optical wiring layer 103, or part of the optical wiring layer 103 may be incorporated into the light input/output unit 109.

Further, as illustrated in FIG. 3E, this package may include an overlap portion 103a in which part of the optical wiring layer 103 and part of the light input/output unit 109 overlap each other. For example, in the overlap portion 103a, part of the light input/output unit 109 is incorporated into the optical wiring layer 103. Also, part of the optical wiring layer 103 may be incorporated into the light input/output unit 109, to form the overlap portion 103a. Part of the optical wiring layer 103 may penetrate the light input/output unit 109, to form the overlap portion 103a in which these components overlap each other. For example, grooves may be provided so as to separate the optical waveguides constituting the optical wiring layer 103 from one another, and convex portions to be fitted in the grooves may be provided on the optical coupling portion of the light input/output unit 109. These grooves and the convex portions are overlapped on each other, to form the overlap portion 103a.

Although not illustrated in the drawings, not only the optical wiring layer 103 but also part of the electrical wiring layer 101 may be incorporated into the light input/output unit 109, or the light input/output unit 109 may be incorporated into part of the electrical wiring layer. In other words, a configuration in which the light input/output unit 109 is optically connected to the optical element 107 or the other optical element 107a via the optical wiring layer 103 may include an overlap portion in which part of the optical wiring layer 103 and/or the electrical wiring layer 101 may penetrate (or be incorporated into) the light input/output unit 109, and the part of the optical wiring layer 103 and/or the electrical wiring layer 101, and the light input/output unit 109 overlap each other.

### EXAMPLE 2

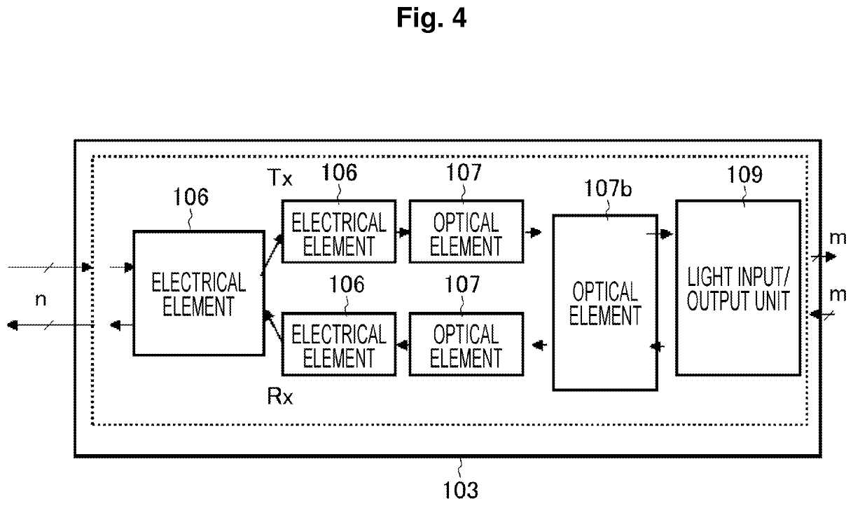

Next, Example 2 is described with reference to FIG. 4. As illustrated in FIG. 4, the optical elements 107 that are an electrical-optical conversion element and an optical-electrical conversion element, and another optical element 107b that is a multiplexer circuit formed by the silicon photonics technology can be formed separately from each other. With this configuration, the optical elements 107 that perform electrical-optical conversion can be formed as EMLs. Note that the electrical element 106 on the left side of FIG. 4 is a PHY device, for example.

### EXAMPLE 3

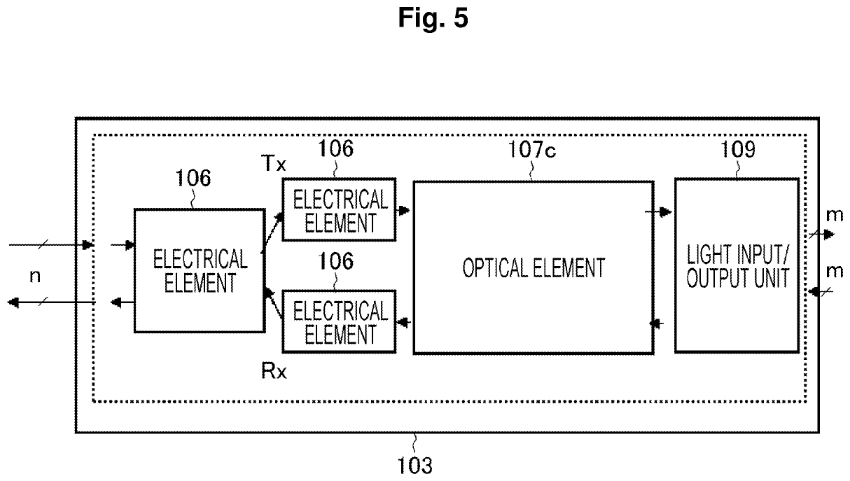

Next, Example 3 is described with reference to FIG. 5. An electrical-optical conversion element, an optical-electrical conversion element, and a multiplexer circuit can be mounted together, to form one optical element 107c. With such a structure, the single optical element 107c is mounted in this module. Accordingly, the number of optical elements requiring high precision in the mounting process can be made smaller than that of the electrical elements 106, and the mounting process can be simplified. Note that the electrical element 106 on the left side of FIG. 5 is a PHY device, for example.

### EXAMPLE 4

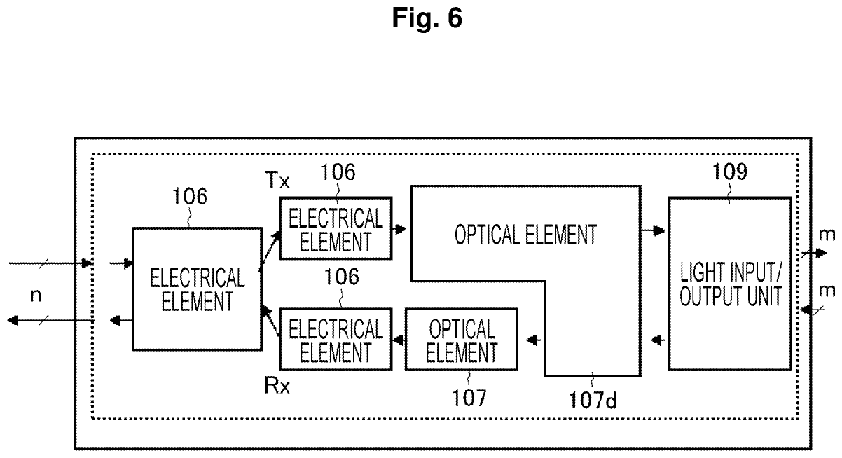

Next, Example 4 is described with reference to FIG. 6. In Example 1, an optical-electrical conversion element and a multiplexer circuit are combined to form the optical element 107a, but an electrical-optical conversion element and a multiplexer circuit may be combined to form an optical element 107d. In this case, the optical element 107 that is an optical-electrical conversion element is formed separately from the multiplexer circuit. For example, the optical-electrical conversion element is a photodiode formed with a compound semiconductor or the like, but is normally a planar semiconductor. Therefore, this kind of optical-electrical conversion element has a high input resistance, and a variable optical attenuator (VOA) that is necessary from the viewpoint of input resistance in an optical-waveguide Ge photodiode becomes unnecessary, and thus, power consumption can be lowered. Note that the electrical element 106 on the left side of FIG. 6 is a PHY device, for example.

### EXAMPLE 5

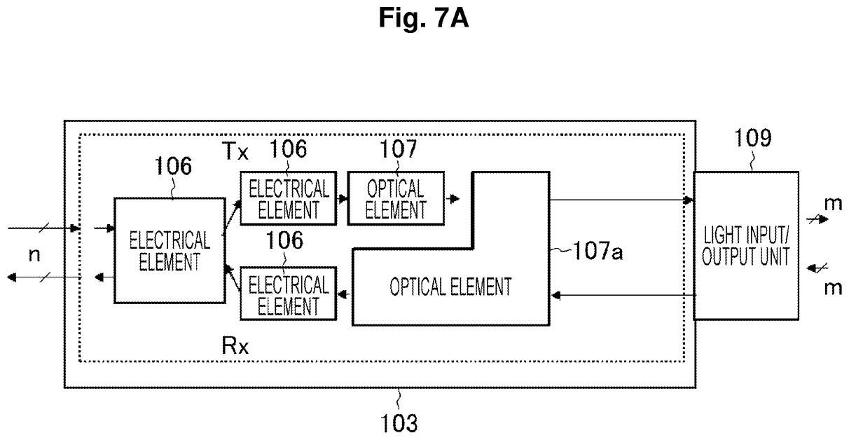

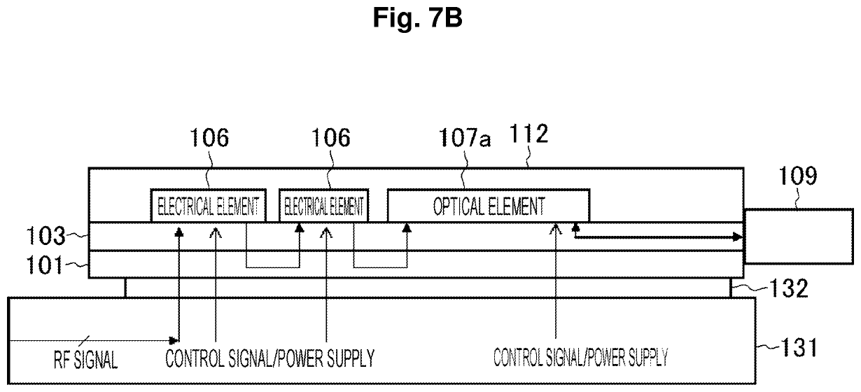

Next, Example 5 is described with reference to FIGS. 7A and 7B. The light input/output unit 109 can be disposed outside the upper region (the module region) of the electrical wiring layer 101. For example, the light input/output unit 109 can be disposed on a side portion of the electrical wiring layer 101 (or the optical wiring layer 103). In this case, the optical wiring layer 103 of the optical wiring layer 103 is formed to extend to the side portion (an end face) of the optical wiring layer 103, and can be optically connected to the light input/output unit 109. The light input/output unit 109 may have a receptacle structure, or may be a fiber array installed on a V-grooved substrate formed with glass or the like. For the optical connection between the side portion (the end face) of the optical wiring layer 103 and the light input/output unit 109, an optical coupling method using spatial propagation in which a gap is formed between the two components may be used, instead of a method for joining the two components with an adhesive or the like, for example.

With the above configuration, it is possible to reduce the number of optical coupling portions in the module. Also, as the light input/output unit 109 is disposed outside, it is possible to use an optical coupling method that is used more widely than conventional technologies. Thus, modules can be manufactured with a high yield. Note that the electrical element 106 on the left side of FIGS. 7A and 7B is a PHY device, for example.

However, the light input/output unit 109 can also be disposed over the electrical wiring layer 101 and on a side portion of the optical wiring layer 103. Also, the light input/output unit 109 can be disposed to overlap part of the structure of the optical wiring layer 103. For example, the light input/output unit 109 can be formed inside the optical wiring layer 103. Also, the optical wiring layer 103 can be included in the light input/output unit 109. Further, the light input/output unit 109 and the optical wiring layer 103 can be disposed so as to overlap each other.

### EXAMPLE 6

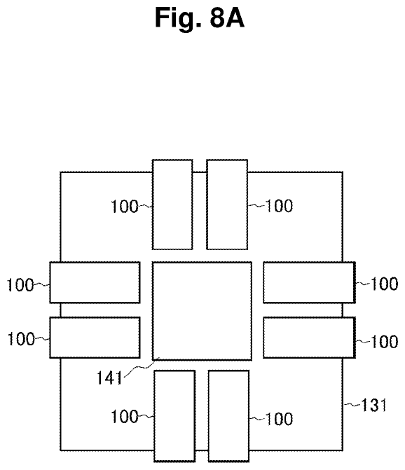

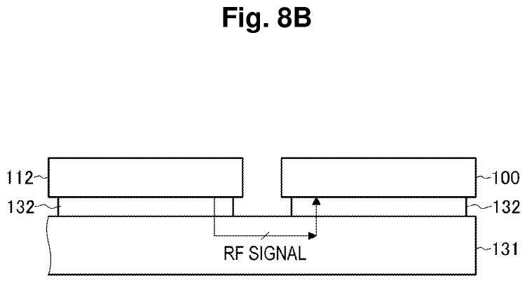

Next, Example 6 is described with reference to FIGS. 8A and 8B. In this example, modules wo described in Examples 1 to 6 are disposed on the module substrate 131 on which a switch ASIC 141 is mounted. On the module substrate 131, a plurality of modules 100 is disposed so as to surround the switch ASIC 141 in a planar view. For example, eight modules 100 of 6.4 Tbps are installed around the switch ASIC 141 having a capacity of 51.2 Tbps, all high-speed I/Os of the switch of 51.2 Tbps can be turned optical on the same module substrate 131, and there is no need to transmit high-speed electrical signals on a printed wiring board. Further, it is not necessary to mount any optical transceiver on the front panel of the switch box, and accordingly, a higher-density optical interface can be achieved.

Standards that specify electrical signals between ASIC and chiplets include the CEI-112G XSR standard of OIF. For example, where this module structure is a module structure (CPO) having a capacity of 6.4 Tbps for both transmission and reception, the transmission capacity per channel (ch) is about 100 Gbps according to CEI-112G XSR mentioned above, and a total of 128 channels, which are 64 transmission channels and 64 reception channels, are required. If each channel has a differential signal configuration of GSSG, for example, the number (n) of electrical input/output terminals needs to be about 500.

The electrical input/output unit 132 formed on the back surface of this module via the electrical wiring layer 101 can two-dimensionally expand the terminals of the mounted chips on the back surface of the module. In an array having a module size of 12 mm×25 mm and a terminal pitch of 0.5 mm, about 1200 terminals can be formed, and the number of power supply terminals of the respective elements and the like can be secured, in addition to the 500 terminals required for inputting and outputting RF signals. Six layers of the polyimide film serving as the insulating layers forming the electrical wiring layer 101 can be stacked, and, in addition to the surface of the polyimide film, two inner layers can be made RF signal layers. Where the module width is about 12 mm, 64 channels for transmission and the same number of channels for reception can be extended in the two inner layers, up to about 200 μm in the pitch between the differential signal channels.

### EXAMPLE 7

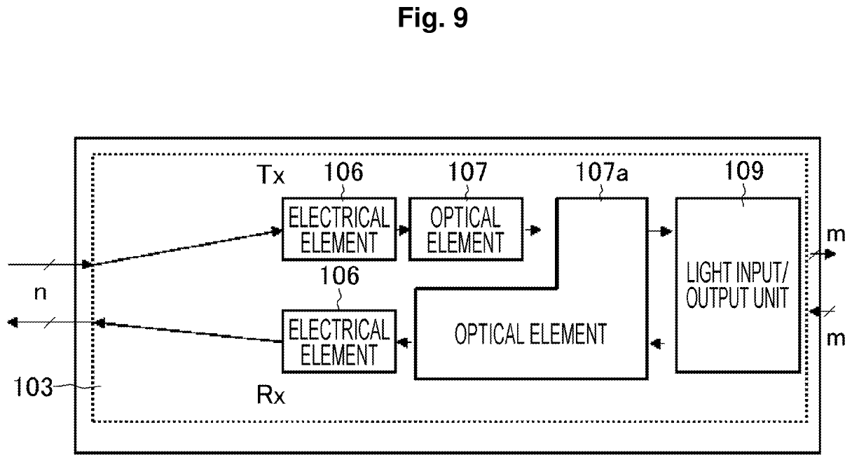

Next, Example 7 is described with reference to FIG. 9. In Examples 1 to 7 described above, PHY devices are used. However, a module can be formed, without a PHY device. For example, PHY chip functions may be integrated in the ASIC existing outside the module, and the module may be directly driven by the ASIC. As this form is adopted, an electrical signal can be input from the immediate vicinity of the plurality of electrical elements 106 present on the module, without passing through a PHY device. Accordingly, the degree of freedom in design becomes higher, or the transmission lines on the module can be reduced. Thus, transmission loss can be reduced.

### EXAMPLE 8

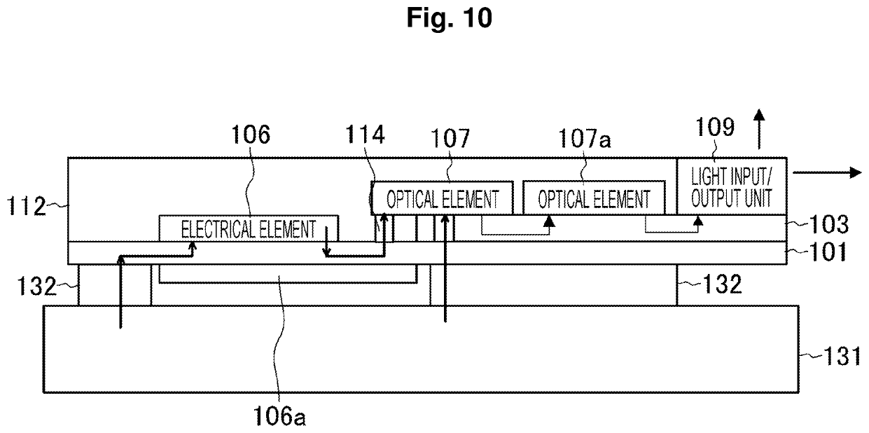

Next, Example 8 is described with reference to FIG. 10. For example, another electrical element 106a such as a PHY device may be disposed on the back surface side of the electrical wiring layer 101, and the electrical element 106, the optical wiring layer 103, and the optical elements 107 and 107a may be disposed on the front surface side of the electrical wiring layer 101. In this case, the electrical input/output unit 132 on the back surface side of the electrical wiring layer 101 is made thicker than the other electrical element 106a.

As such a form is adopted, the electrical element 106 can be disposed to overlap the other electrical element 106a formed with a PHY device in a planar view, and the module size can be reduced. If necessary, a pillar 114 formed with a metal such as Cu may be formed in the protective layer 112 that has already been formed, so that electrical connection can be established with the electrical element 106, the optical element 107, and the like disposed on the front surface side of the electrical wiring layer 101 via the electrical wiring layer 101.

Note that not only a PHY device but also an electrical element such as a thin-film capacitor and an electrical element such as a memory can be disposed on the back surface of the electrical wiring layer 101. Normally, for RF signals, bias voltages vary among components (elements). Therefore, a DC block or the like is required, or a capacitor for bypassing is disposed at a power supply terminal near a chip so as to increase the stability of the power supply. On the other hand, as a two-stage configuration is adopted as described above, the upper portions of the passive components can also be used as electrical wiring lines or optical wiring lines, and the module size can be made smaller.

### EXAMPLE 9

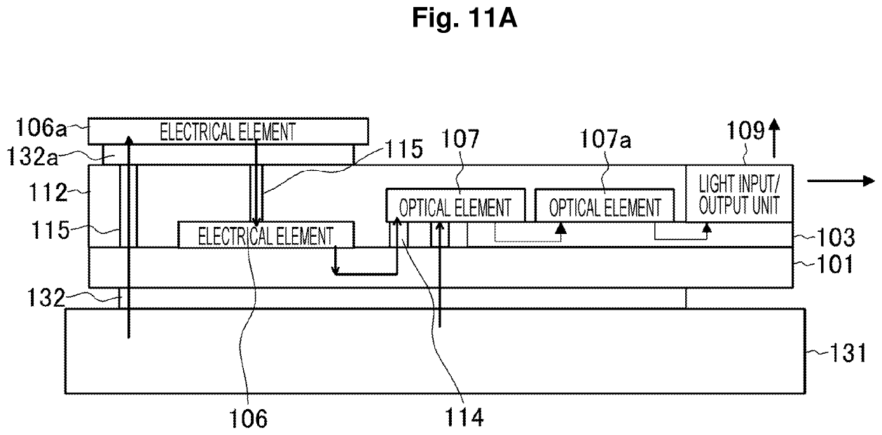

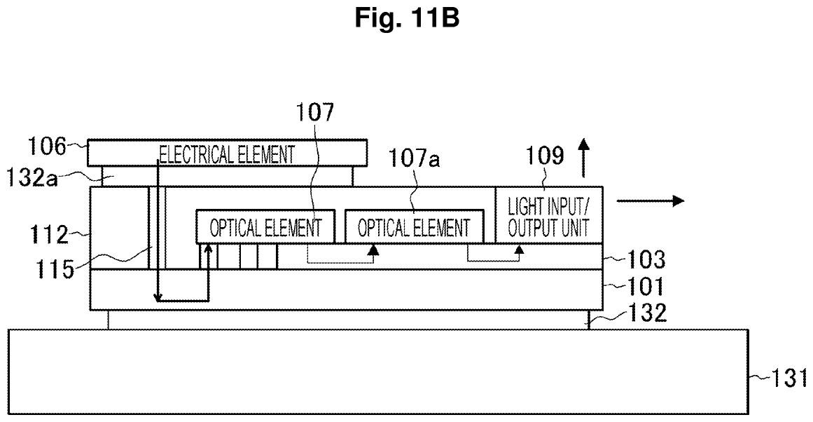

Next, Example 9 is described with reference to FIGS. 11A and 11B. In the manufacture of this module, it is also possible to form the protective layer 112, after forming the electrical wiring layer 101 and the optical wiring layer 103, and disposing the electrical element 106, the optical elements 107 and 107a, and the light input/output unit 109 via the electrical input/output unit 132 or the optical coupling portion. As another electrical input/output unit 132a is provided on one surface of the module via metal pillars 115 formed with Cu or the like beforehand in the electrical wiring layer 101, a two-story configuration can be obtained.

For example, the other electrical element 106a formed with a PHY device can be disposed in the second floor portion. Further, as illustrated in FIG. 11B, a two-story configuration can be formed with a pillar 115, the electrical input/output unit 132a, and the like, and the electrical element 106 can be installed outside the protective layer 112. In this case, there are no electrical elements in the protective layer 112, and the electrical element 106 is mounted only on the upper surface of the electrical input/output unit 132a provided on an upper portion of the protective layer 112. Note that, in the above description, the step of forming the optical wiring layer 103 is carried out after the step of forming the electrical wiring layer 101. However, the optical wiring layer 103 may be formed first, and after that, the electrical wiring layer 101 may be formed.

### Second Embodiment

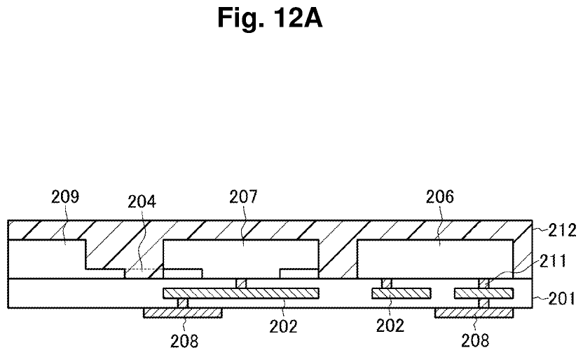

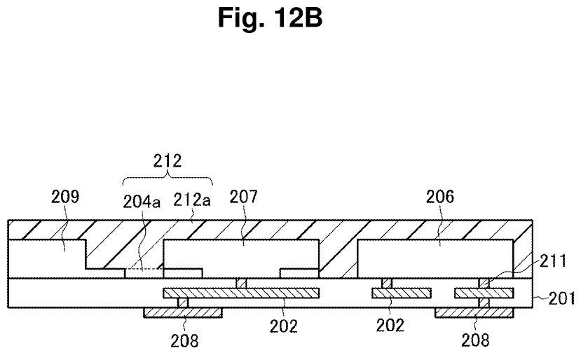

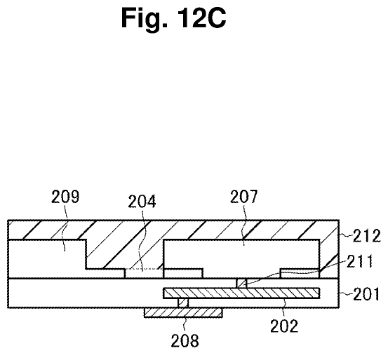

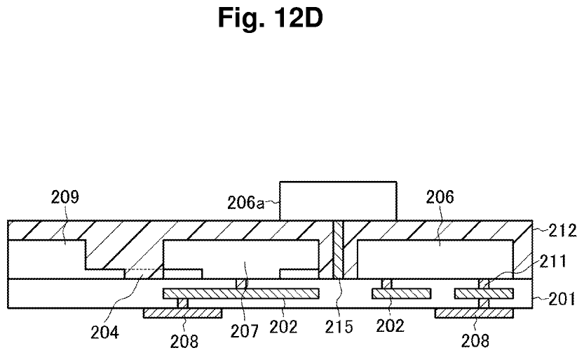

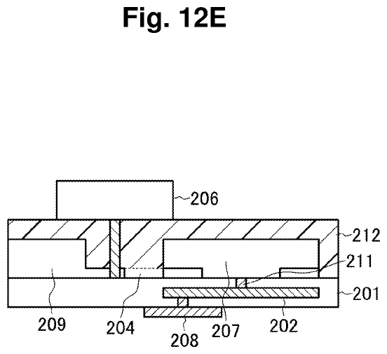

Next, an optical semiconductor module according to a second embodiment of the present invention is described with reference to FIGS. 12A and 12B.

This semiconductor module includes an electrical wiring layer 201, an electrical element 206, and an optical element 207. The electrical wiring layer 201 includes electrical wiring lines 202 for propagating electrical signals. The electrical element 206 is formed on the electrical wiring layer 201 and is electrically connected to the electrical wiring lines 202. The electrical element 206 is electrically connected to the electrical wiring lines 202 via contact wiring lines 211, for example. The electrical wiring lines 202 extend in a plane direction of the electrical wiring layer 201. Further, terminals 208 are formed on the back surface of the electrical wiring layer 201, and are electrically connected to the electrical wiring lines 202.

The optical element 207 can be a light emitting element such as a semiconductor laser or a light emitting diode, a photoelectric conversion element such as a photodiode, or an optical modulation element, for example. Alternatively, the optical element 207 can be an element that includes a light receiving unit designed by a well-known silicon photonics technology, and a multiplexer/demultiplexer formed with an optical waveguide.

The electrical element 206 can be a driver element for driving the optical element 207 formed with an element as described above, a TIA for amplifying a photoelectrically converted signal, or a PHY device, for example. The electrical element 206 can also be a programmable logic device such as an FPGA.

Also, the electrical element 206 can be in the form of a bare chip, a subcarrier-mounted form, the form of a CSP, or the like. Alternatively, the electrical element 206 can have a structure in which chips are stacked in multiple stages. Meanwhile, the terminals 208 can be solder bumps, solder balls, or copper pillars, for example.

The optical element 207 is formed on the electrical wiring layer 201, and is optically coupled to a light propagation portion 204. The light propagation portion 204 is disposed between the optical element 207 and another optical element optically connected to the optical element 207, and propagates light for optical connection between the optical element 207 and the other optical element in a plane direction of the electrical wiring layer 201.

The light propagation portion 204 may be formed with an optical system disposed between the optical element 207 and the other optical element adjacent to the optical element 207, for example. Also, the light propagation portion 204 can have a connection configuration in which the optical element 207 and the other optical element are connected by an edge coupling method. The other optical element is a light input/output unit 209, for example. The light input/output unit 209 is optically connected to the optical element 207 via the light propagation portion 204, and realizes connection between this module and an optical fiber, for example. The light input/output unit 209 can be an MT ferrule having a structure similar to that of a well-known MT connector, for example. The MT ferrule contains a plurality of short fibers, for example.

Further, optical connection between a plurality of optical elements disposed on the electrical wiring layer 201 as illustrated in Examples 1 to 6 of the first embodiment is established by the light propagation portion 204. Optical connection can be established between the optical coupling portions of the plurality of optical elements by an edge coupling method for connecting the respective optical coupling portions via the light propagation portion 204, or by a coupling method using resin spatial propagation.

The light propagation portion 204 can be formed with resin, for example. The resin material preferably has high transparency, a matching refractive index, and small variation in the thermal expansion coefficient. For example, in a case where an optical element having a wavelength in the 1.55 μm band is used, the material to be used may be an acrylic resin having transparency and a refractive index of about 1.5, an epoxy resin, silicone (polysiloxane), a fluorinated polymer, a fluorinated polyimide, polynorbornene, oxetane, an organic-inorganic hybrid material, a substitution material of any of these materials, or the like.

Also, a protective layer 212 is formed over the electrical wiring layer 201 so as to cover the optical element 207. In this example, the protective layer 212 also covers the electrical element 206. The protective layer 212 is a component for sealing each element, and can be formed with a cured resin such as epoxy, for example. Although not illustrated in the drawings, the optical element 207 may include an optical connector that is optically connected to the optical element 207.

Although not illustrated either, a heat dissipation member such as a heat sink can be provided on and in contact with the electrical element 206 and the optical element 207. Here, in a case where the protective layer 212 is formed with a transparent resin that transmits light having a target wavelength as described above, the light propagation portion 204 can be formed with the portion of the protective layer 212 disposed (filling) between the optical element 207 and the other optical element. In this case, the light propagation portion 204 is formed with part of the protective layer 212. The optical semiconductor module according to the second embodiment can have the same configuration as that of the first embodiment described above, except for the configuration in which the optical connection between the optical elements is established by the light propagation portion 204.

Here, the electrical wiring layer 201 has a thickness of about several microns to several tens of microns. Further, the electrical wiring layer 201 can have a so-called multi-layer wiring structure. Even having a multi-layer structure, the electrical wiring layer 201 maintains the form of a film. The electrical wiring layer 201 that is in the form of a thin film serves as the base surface on which the electrical element 206 and the optical element 207 are mounted, but is clearly different from a rigid and thick substrate that is used in a conventional module.

Therefore, to provide the module with strength, the electrical element 206, the optical element 207, and the light input/output unit 209 are sealed with the protective layer 212 so that the mechanical strength is enhanced. Having the protective layer 212 formed with cured resin (plastic), the module having the protective layer 212 formed thereon can obtain a mechanical strength comparable to that of a module formed on a conventional rigid and thick substrate.

In the second embodiment, the optical element 207 and the other optical element are optically connected by the light propagation portion 204. For example, there are cases where the optical element formed by the silicon photonics technology and the optical element 207 including a PLC, and the light input/output unit 209 adjacent thereto are optically connected by the light propagation portion 204 according to a spatial optical method or an edge coupling method.

In such a case, a resin having optical transparency or a refractive index matching function can be used as a first molding resin formed in contact with each optical element. Alternatively, it is also possible to apply and form a second molding resin for further enhancing sealing and strength on the first molding resin described above. In this manner, the impact resistance and the moisture resistance of the module body can be increased, without degradation of the optical characteristics in the portion serving as the light propagation portion 204.

Further, the protective layer 212 can be formed by overlapping and applying a plurality of molding materials. In other words, the protective layer 212 can have a multi-layer structure formed with different resins. For example, as illustrated in FIG. 12B, the protective layer 212 may include a first protective layer 204a and a second protective layer 212a. The first protective layer 204a is the light propagation portion described above, and can be used as an underfill material for the purpose of abbreviating the stress on the elements, for example.

Meanwhile, as illustrated in FIG. 12C, it is also possible to adopt a configuration in which the optical element 207 is provided on the electrical wiring layer 201, and the module does not include any electrical element. For example, by adopting the form of a direct drive, it becomes possible to connect a plurality of modules that do not include any electrical element but include the optical element 207 with one switch ASIC, as described above with reference to FIGS. 8A and 8B. Note that, in this module, the optical element 207 is also formed on the electrical wiring layer 201, and is optically coupled to the light propagation portion 204. The light propagation portion 204 is disposed between the optical element 207 and another optical element optically connected to the optical element 207, and propagates light for optical connection between the optical element 207 and the other optical element in a plane direction of the electrical wiring layer 201. Also, a protective layer 212 is formed over the electrical wiring layer 201 so as to cover the optical element 207.

Further, as illustrated in FIG. 12D, it is possible to adopt a two-story configuration in which electrical connection is established through a metal pillar (a through electrode) 215 that is formed with Cu or the like beforehand in the electrical wiring layer 201. For example, another electrical element 206a formed with a PHY device can be disposed in the second floor portion. In this configuration, the other electrical element 206a can be mounted on the upper surface of an electrical input/output unit (not illustrated) provided on an upper portion of the protective layer 212.

Furthermore, as illustrated in FIG. 12E, the electrical element 206 may not be included in the protective layer 212. In this configuration, the electrical element 206 can be mounted only on the upper surface of an electrical input/output unit (not illustrated) provided on an upper portion of the protective layer 212. Although not illustrated in the drawings, another electrical element such as a PHY device may be disposed on the back surface side of the electrical wiring layer 201, for example. As such a form is adopted, the module size can be reduced.

Here, another method for manufacturing an optical semiconductor module is described. First, in the first step, an optical wiring layer including optical wiring lines for propagating optical signals is formed over a support substrate. Next, in the second step, an electrical wiring layer including electrical wiring lines for propagating electrical signals and supplying electrical power is formed over the support substrate. Next, in the third step, an electrical element is mounted on the electrical wiring layer, and the electrical element is electrically connected to the electrical wiring lines. Next, in the fourth step, an optical element is mounted on the optical wiring layer, and the optical element is optically connected to the optical wiring lines. Next, in the fifth step, resin sealing is performed with one or more kinds of resins. Next, in the sixth step, the support substrate is removed. Here, in a case where the first step, the second step, the third step, and the like described above are carried out at a wafer level or a panel level, the module is further divided into individual modules in the seventh step.

Further, by yet another method for manufacturing an optical semiconductor module, an electrical wiring layer including electrical wiring lines for propagating electrical signals and supplying electrical power is formed over a support substrate in the first step. Next, in the second step, an electrical element and/or an optical element is mounted on the electrical wiring layer, and the electrical element is electrically connected to the electrical wiring lines. Next, in the third step, the mounted optical element is optically connected to the optical wiring lines. Next, in the fourth step, resin sealing is performed with one or more kinds of resins. Next, in the fifth step, the support substrate is removed. Here, in a case where the first step, the second step, the third step, and the like described above are carried out at a wafer level or a panel level, the module is further divided into individual modules in the seventh step.

Also, each of the optical semiconductor module manufacturing methods described above may include a step of forming a light input/output unit before performing resin sealing. Alternatively, each of the optical semiconductor module manufacturing methods described above may include a step of forming a light input/output unit, before or after the step of dividing the module into individual modules.

As described above, according to embodiments of the present invention, an electrical element and an optical element are disposed over an electrical wiring layer including electrical wiring lines for propagating electrical signals. Thus, the module size can be made smaller, and mounting can be performed at a higher density.

Conventionally, in module manufacturing, it is necessary to carry out the step of bonding and securing optical fibers after precisely aligning the optical fibers with the optical devices to be mounted in the module. Also, to increase the strength of the bonding portion, it is necessary to carry out the step of providing not only a contact point between an optical device and an optical fiber, but also a bonding portion on the support substrate supporting the optical device and the optical fiber (Non Patent Literature 1, FIG. 1). Particularly, in an optical module for communication, a structure that leads the optical fibers out of the housing is also necessary, and assembling needs to be performed with great care, because there are a large number of joining portions for securing the fibers. As is apparent from these complicated structures and steps, conventional modules have a problem in mass productivity.

According to embodiments of the present invention, there is no need to provide components such as optical fibers in a module. Thus, manufacturing can be performed with steps that are less complicated compared with those according to a conventional technology, and higher mass productivity can be achieved with smaller modules.

Further, a protective layer that is formed with cured resin and covers the electrical element and the optical element is provided over the electrical wiring layer. Thus, the mechanical strength of the module can be increased.

Note that the present invention is not limited to the embodiments described above, and it is obvious that many modifications and combinations can be implemented by a person having ordinary knowledge in the art within the technical idea of the present invention.

1.-37. (canceled)

38. An optical semiconductor module comprising:
an electrical wiring layer comprising an electrical wiring line configured to propagate an electrical signal and supply electrical power;
an optical wiring layer over or under the electrical wiring layer and comprising an optical wiring line configured to propagate an optical signal; and
an optical element on the optical wiring layer, electrically connected to the electrical wiring layer, and optically connected to the optical wiring line.

39. The optical semiconductor module according to claim 38, wherein the electrical wiring line and the optical wiring line extend in a plane direction of the electrical wiring layer.

40. The optical semiconductor module according to claim 38, further comprising a light propagation portion disposed between the optical element and another optical element optically connected to the optical element, the light propagation portion configured to propagate light in a plane direction of the electrical wiring layer, the light being for optical connection between the optical element and the another optical element.

41. The optical semiconductor module according to claim 38, further comprising a protective layer on a front surface of the electrical wiring layer and covering the optical element.

42. The optical semiconductor module according to claim 41, wherein the protective layer comprises a cured resin.

43. The optical semiconductor module according to claim 41, wherein the protective layer has a multi-layer structure comprising different kinds of resins.

44. The optical semiconductor module according to claim 38, further comprising an electrical element on the electrical wiring layer and electrically connected to the electrical wiring line.

45. The optical semiconductor module according to claim 38, further comprising a light input/output device that is optically connected to the optical element.

46. The optical semiconductor module according to claim 45, wherein:
the light input/output device penetrates the electrical wiring layer in a thickness direction from a front surface of the electrical wiring layer on a bottom surface side of the light input/output device; and
the optical semiconductor module further comprises an overlap portion in which the light input/output device and the electrical wiring layer overlap each other.

47. The optical semiconductor module according to claim 45, wherein:
the light input/output device is optically connected to the optical element via the optical wiring layer; and
the optical semiconductor module further comprises an overlap portion in which part of the optical wiring layer or the electrical wiring layer penetrates a light input/output portion, and the part of the optical wiring layer or the electrical wiring layer and the light input/output device overlap each other.

48. The optical semiconductor module according to claim 45, further comprising:
another electrical element that is electrically connected to a back surface side of the electrical wiring layer; and
an electrical input/output device that is thicker than the another electrical element and is disposed on the back surface side of the electrical wiring layer.

49. The optical semiconductor module according to claim 45, further comprising:
electrical input/output devices disposed on each of an upper surface of a protective layer and a back surface side of the electrical wiring layer, wherein the protective layer is on a front surface of the electrical wiring layer;
a through electrode to which each of the electrical input/output devices is electrically connected via the electrical wiring layer and through the protective layer; and
an electrical element disposed on an upper surface of the electrical input/output device that is disposed on the upper surface of the protective layer.

50. The optical semiconductor module according to claim 49, further comprising another electrical element mounted only on the upper surface of the electrical input/output device that is disposed over the protective layer.

51. The optical semiconductor module according to claim 38, further comprising a light propagation portion configured to propagate light in a plane direction of the electrical wiring layer, the light being for optical connection with the optical element.

52. The optical semiconductor module according to claim 38, further comprising a terminal on a back surface of the electrical wiring layer and electrically connected to the electrical wiring line.

53. An optical semiconductor module manufacturing method, the method comprising:
forming an electrical wiring layer over a support substrate, the electrical wiring layer comprising an electrical wiring line that propagates an electrical signal and supplies electrical power;
forming an optical wiring layer over the support substrate, the optical wiring layer comprising an optical wiring line that propagates an optical signal;
mounting an electrical element on the electrical wiring layer and electrically connecting the electrical element to the electrical wiring line;
mounting an optical element on the optical wiring layer and optically connecting the optical element to the optical wiring line;
performing resin sealing;
removing the support substrate; and
dividing a resultant module into individual modules; and
wherein forming the electrical wiring layer, forming the optical wiring layer, and mounting the electrical element are performed at a wafer level or a panel level.

54. The method according to claim 53, wherein the electrical wiring line and the optical wiring line extend in a plane direction of the support substrate.

55. An optical semiconductor module manufacturing method, the method comprising:
forming an electrical wiring layer over a support substrate, the electrical wiring layer comprising an electrical wiring line that propagates an electrical signal and supplies electrical power;
mounting an electrical element and an optical element on the electrical wiring layer;
electrically connecting the electrical element to the electrical wiring line;
optically connecting the optical element to an optical wiring line;
performing resin sealing;
removing the support substrate; and
dividing a resultant module into individual modules; and
wherein forming the electrical wiring layer, mounting the electrical element and the optical element, electrically connecting the electrical element, and optically connecting the optical element are performed at a wafer level or a panel level.

56. The method according to claim 55, wherein the electrical wiring line extends in a plane direction of the support substrate.

57. The method according to claim 55, further comprising:
forming a light input/output device before performing the resin sealing; or
forming the light input/output device before or after dividing the resultant module into the individual modules.
